(19) United States
(12) Patent Application Publication
(10) Pub. No.: US 2016/0187776 A1
(43) Pub. Date: Jun. 30, 2016

(54) COMPOUND FOR SEMICONDUCTOR PACKAGE, PHOTOSENSITIVE RESIN COMPOSITION INCLUDING THE SAME AND SEMICONDUCTOR PACKAGE STRUCTURE THEREOF

(71) Applicant: GTA ELECTRONICS CO., LTD., New Taipei City (TW)

(72) Inventor: YUNG-CHI TSAI, New Taipei City (TW)

(21) Appl. No.: 14/585,899

(22) Filed: Dec. 30, 2014

(51) Int. Cl. G03F 7/038; H01L 23/29; C07F 7/18

(52) U.S. Cl. CPC G03F 7/0384; C07F 7/184; H01L 23/296

(57) ABSTRACT

A compound represented by Formula 1, a photosensitive resin composition including the compound represented by Formula 1, and a semiconductor package structure using the photosensitive resin are disclosed, wherein the Formula 1 is as follows, and n is an integer of 1 to 15:

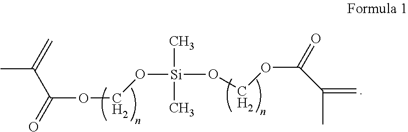

### BACKGROUND OF THE INVENTION

1. Field of the Invention

The present invention relates to a compound for a semiconductor package, a photosensitive resin composition including the same, and a semiconductor package structure thereof.

2. Description of the Related Art

Polyimides (PI) are widely used in semiconductor industry because of having the advantages such as wide temperature range applications, chemical resistance, high strength, good weatherability, radiation resistance, and excellent electrical properties. Polyimides are mainly used as films and coating in IC coating, adhesive and encapsulation processes. When the polyimides serve as coating materials, polyimides may be used as protective films for IC and interlayer insulating layers for multilayer wires. When the polyimides serve as adhesive materials, they may adhere to IC with a lead frame. When the polyimides serve as encapsulation materials, they encapsulate IC on a lead frame.

Polyimides are usually classified into non-photosensitive polyimides and photosensitive polyimides. The photosensitive polyimides are also called photoreactive polyimides, which are only sensitive to high-energy radiation, such as UV light, laser, electron beam, ion beam, etc. Thus, the photosensitive polyimides can be used in semiconductor manufacturing processes which form a circuit pattern by using a development process. When the photosensitive polyimide is used in the development process, different from common photoresists which would be removed after exposure and development processes, the photosensitive polyimide may be remained on a semiconductor element after exposure and development process, and thus the semiconductor manufacturing processes can be simplified by omitting the step of removing the photoresist.

The photosensitive polyimides are usually classified into positive-type photosensitive polyimides and negative-type photosensitive polyimides. Solubility of exposed portions of the positive-type photosensitive polyimides may increase after light exposure such that appropriate solvent may be used to dissolve the exposed portions of the positive-type photosensitive polyimides. On the other hand, solubility of exposed portions of the negative-type photosensitive polyimides may decrease after light exposure such that appropriate solvent may be used to dissolve the non-exposed portions of the negative-type photosensitive polyimides.

Toray Industries Inc. (Japan) (U.S. Patent Application No. 20110284855 and U.S. Patent Application No. 20140005318) and Sony Chemical & Information Device Corp. (Japan) (U.S. Pat. No. 8,445,621) provide a novel photosensitive polyimide, which is more suitable for manufacturing a semiconductor element than traditional polyimides. The novel photosensitive polyimides may be mixed with crosslinkers to form a mixture. After the mixture was exposed to light, the polyimides and the crosslinkers may carry out a cross-linking reaction to form patterns due to the difference in solubility. However, to fulfill the need for thinner, lighter, and higher resolution of the semiconductor element, a photosensitive resin composition including a photosensitive polyimide with improved properties is required.

### SUMMARY OF THE INVENTION

In the view of the above-stated problems in the prior art, the object of the present invention is to provide a compound which may be served as a crosslinker to further improve the resolution, an photosensitive resin composition including the compound with improved properties and a semiconductor package structure thereof.

According to an object of the present invention, providing a compound represented by Formula 1,

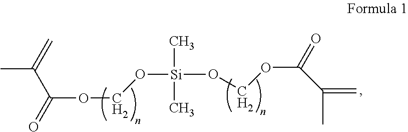

wherein n is an integer of 1 to 15.

According to another object of the present invention, providing a photosensitive resin composition, which comprises the compound represented by Formula 1, a photoinitiator, and a photosensitive polyimide.

The photosensitive polyimide preferred comprises an aromatic polyimide backbone, a first side chain, and a second side chain, wherein the first side chain and the second side chain each include a (meth)acryloyl group grafted to the aromatic polyimide backbone.

The aromatic polyimide backbone preferred comprises a repeating unit A represented by one of Formula 1-1, Formula 1-2, and Formula 1-3, or the combination thereof:

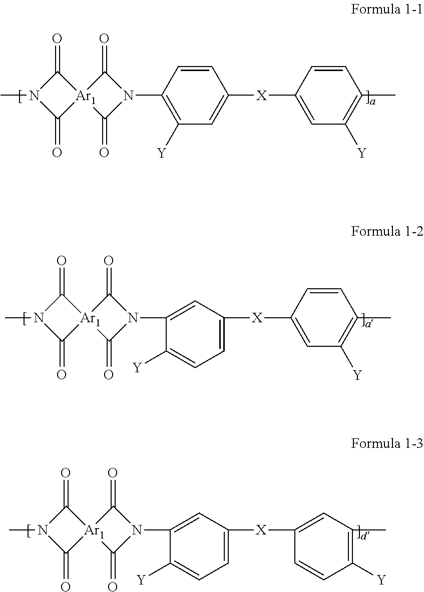

wherein Ar₁ is one of

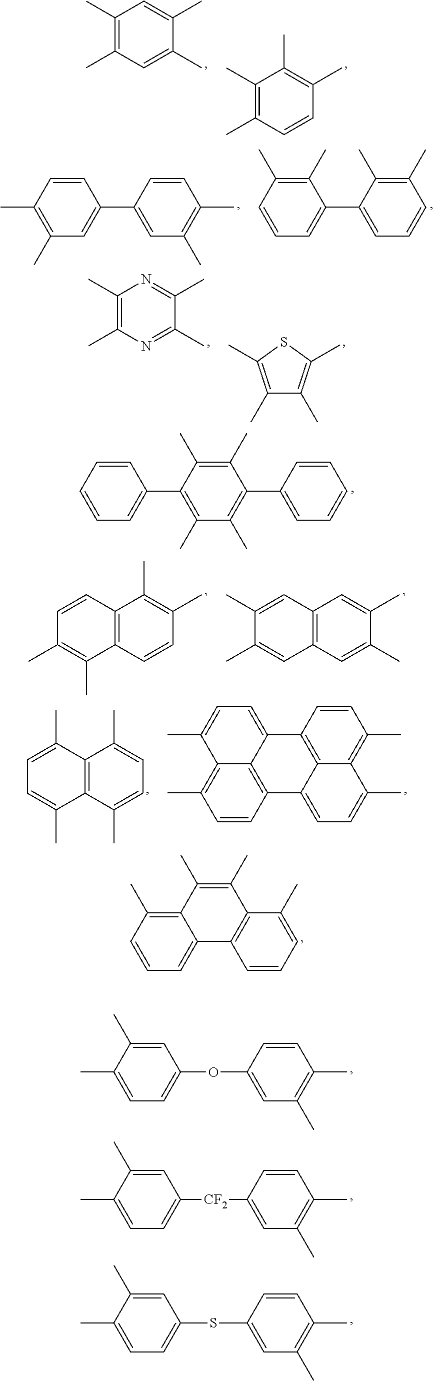

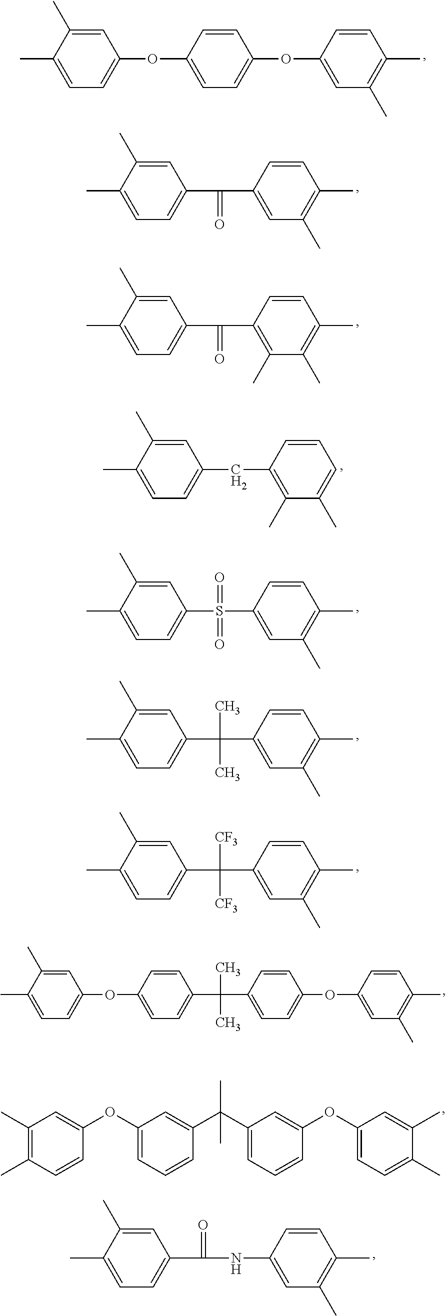

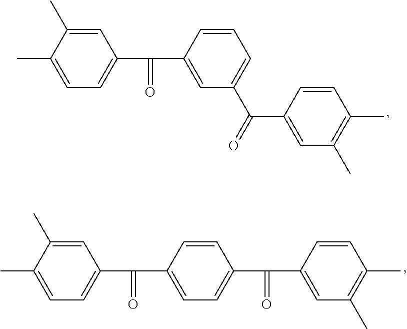

and a combination thereof.

### X is one of

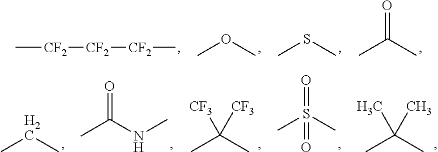

and a combination thereof.
Y is —O— which is bounded to the first side chain and the second side chain, and a, a′, and a″ each are independently an integer of 1 or more.

The photosensitive polyimide is preferred represented by Formula 1-A:

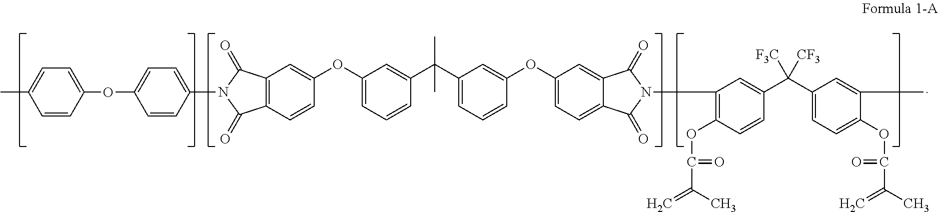

The photosensitive polyimide is preferred represented by Formula 1-B:

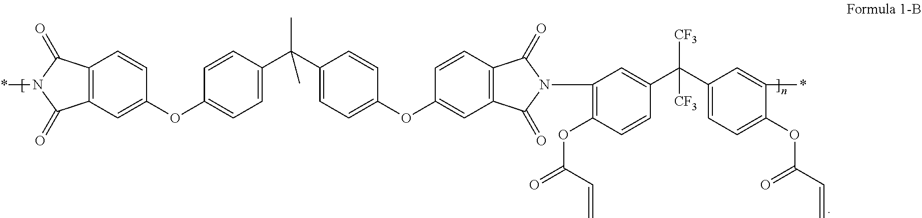

In addition, the present invention further provides a semiconductor package, which comprises a plurality of semiconductor chips and an insulation layer encapsulating the plurality of semiconductor chips, wherein the insulation layer is formed by curing the photosensitive resin composition comprising the compound represented by Formula 1, a photoinitiator, and a photosensitive polyimide.

The photosensitive polyimide included in the photosensitive resin composition is a photosensitive polyimide which is preferred represented by Formula 1-A and Formula 1-B above.

The photosensitive resin composition comprising the foregoing compound and the photosensitive polyimide which provided by the present invention may be used in a semiconductor element manufacturing to achieve the purpose which reduce the steps of the semiconductor element manufacturing and improve the resolution of the semiconductor element, and thus provides a semiconductor package structure with improved properties.

### BRIEF DESCRIPTION OF THE DRAWINGS

The detailed structure, operating principle and effects of the present invention will now be described in more details hereinafter with reference to the accompanying drawings that show various embodiments of the invention as follows:

FIG. 1 is an NMR spectrum of the compound represented by Formula 1;

FIG. 2a is a view showing the experimental result of the example according to an embodiment of the present invention; and

FIG. 2b is a view showing the experimental result of the comparative example.

### DETAILED DESCRIPTION OF THE PREFERRED EMBODIMENTS

The present invention will now be described more fully with reference to the accompanying drawings. The invention may be embodied in many different forms, and should not be construed as being limited to the embodiments set forth herein. Rather, these embodiments are provided so that this disclosure will be thorough and complete, and will fully convey the concept of the invention to one of ordinary skill in the art.

Unless otherwise defined, all terms (including technical and scientific terms) used herein have the same meaning as commonly understood by one of ordinary skill in the art to which this invention belongs. It will be further understood that terms, such as those defined in commonly used dictionaries, should be interpreted as having a meaning that is consistent with their meaning in the context of the relevant art and the disclosure, and will not be interpreted in an idealized or overly formal sense unless expressly so defined herein.

The polyimides used for a semiconductor package can be classified into photosensitive polyimides and non-photosensitive polyimides. The present invention provides a photosensitive resin composition including a photosensitive polyimide for a semiconductor package. The embodiment of the present invention discloses a compound which may replace known crosslinker and silane coupling agents. Comparing with known photosensitive resin composition including a photosensitive polyimide, crosslinker, a photoinitiator, and silane coupling agents, the photosensitive resin composition of the present invention may only include a compound used as crosslinker, a photoinitiator, and a photosensitive polyimide, and may have better resolution.

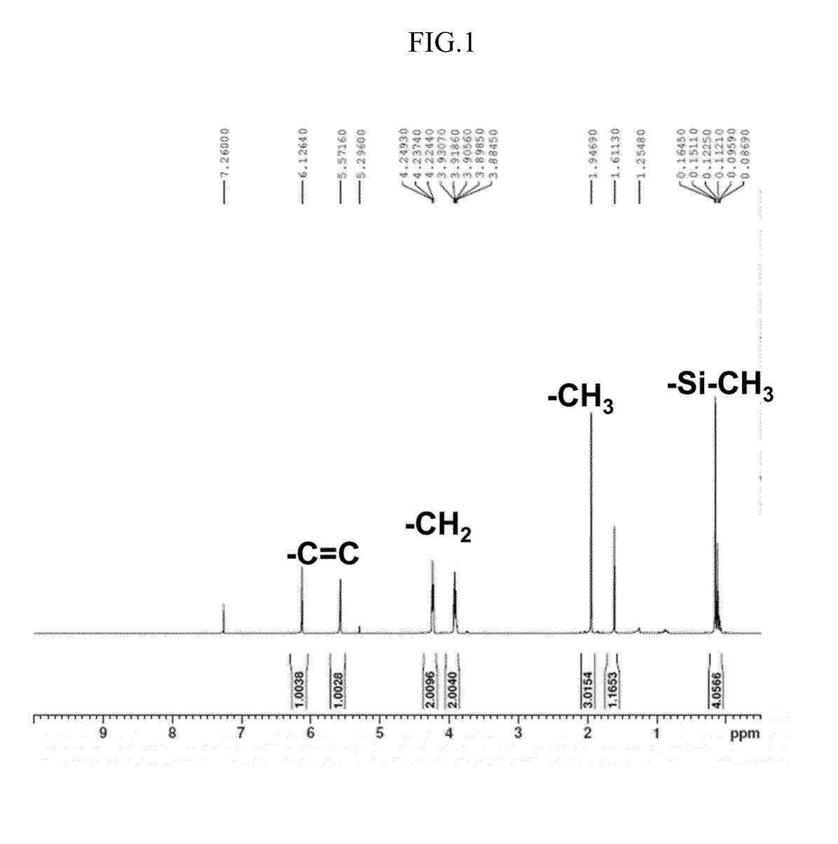

The compound according to an embodiment of the present invention which can be served as a crosslinker may be represented by Formula 1, wherein n is an integer of 1 to 15. FIG. 1 is an NMR spectrum of the compound represented by Formula 1.

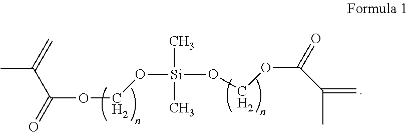

The compound represented by Formula 1 may be formed by reacting dimethyldichlorosilane with a compound having the group:

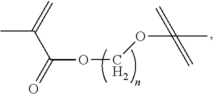

for example, hydroxyethyl methacrylate (HEMA) or HEMA acetoacetate.

When n=2, an example of the compound represented by Formula 1 may be formed by the following process:

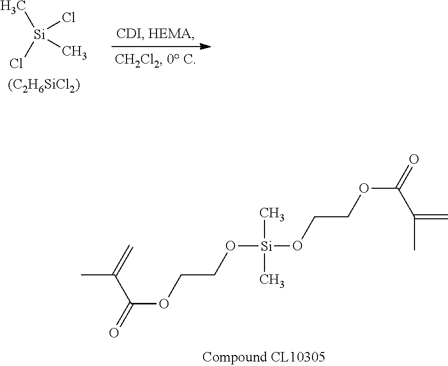

3 g (0.010 mol) of HEMA was dissolved in 5 mL of CH₂Cl₂ under an N₂ atmosphere, and 7.5 g (0.046 mol) of CDI (1,1′-carbonyldiimidazole) was added thereto in an ice bath. After the solid was dissolved, 2.9 g (0.010 mol) of C₂H₆SiCl₂ was slowly dropwise added thereto. After 4 hrs reaction, the resultant was extracted with water three times (5 mL each time). An organic layer was collected and dehydrated with magnesium sulfate, and then filtered and drained to obtain a light yellow liquid. The resulting product was further purified by column chromatography (EA:n-Hexane=1:1) to obtain 3.51 g (Yield: 75%) of compound CL10305, which is a transparent liquid.

In one embodiment of the present invention, the photosensitive polyimide may be formed by reacting an aromatic polyimide having at least two reactive terminal groups with a compound having photosensitive group.

The aromatic polyimide having at least two reactive terminal groups may be formed by react an aromatic dianhydride represented by Formula 2 with a diamine.

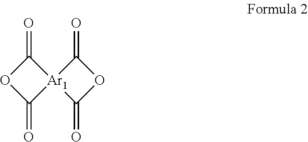

In the Formula 2, An may be one of

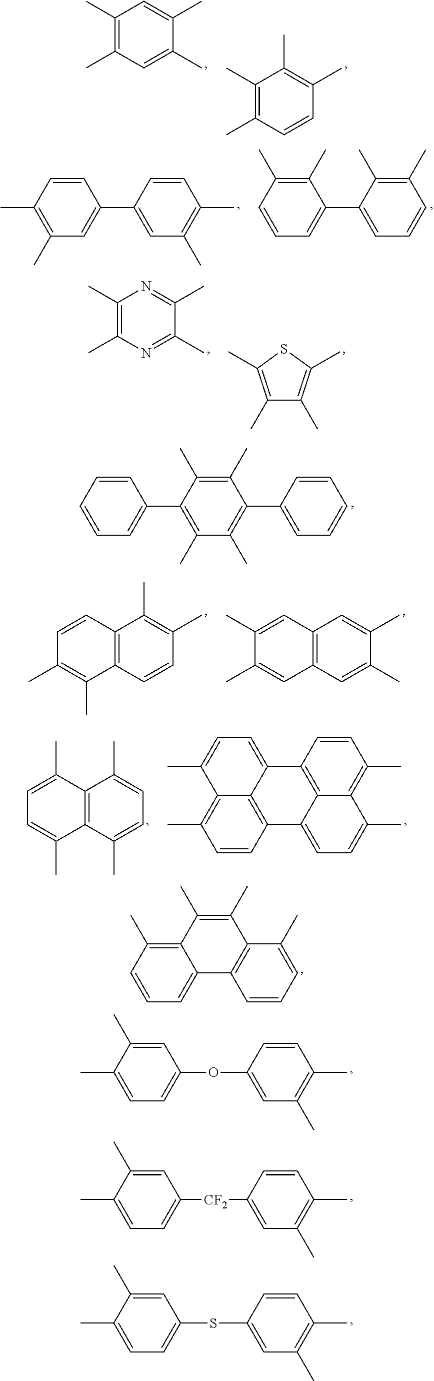

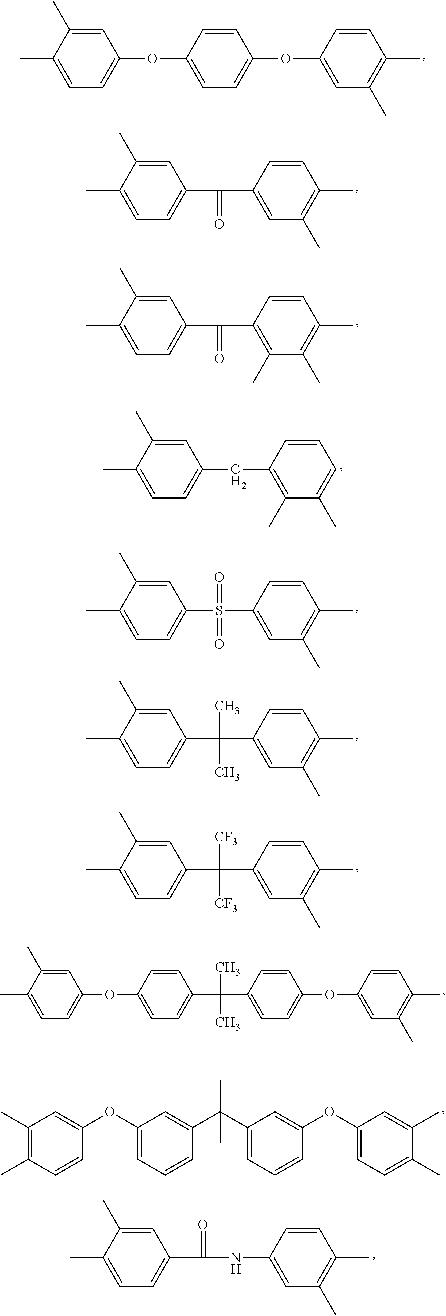

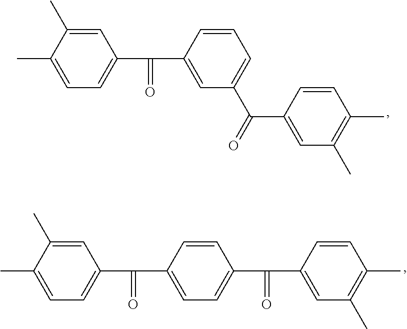

and a combination thereof.

Exemplary aromatic dianhydrides of Formula 2 include but not limited to pyromellitic dianhydride (PMDA), bisphenol A dianhydride (BPADA), 3,3′,4,4′-biphenyltetracarboxylic dianhydride, 2,2′,3,3′-biphenyltetracarboxylic dianhydride, 2,3,3′,4′-biphenyltetracarboxylic dianhydride, 4,4′-(hexafluoroisopropylidene)-diphthalic anhydride (6FDA), 1-(trifluoromethyl) benzene-2,3,5,6-tetracarboxylic acid dianhydride (P3FDA), 1,4-bis(trifluoromethyl)-2,3,5,6-benzene tetracarboxylic dianhydride (P6FDA), 3,3′,4,4′-benzophenonetetracarboxylic dianhydride, 1,4,5,8-naphthalenetetracarboxylic dianhydride, 2,6-dichloro-naphthalene-1,4,5,8-tetracarboxylic dianhydride, 2,7-dichloro-naphthalene-1,4,5,8-tetracarboxylic acid dianhydride, 1,2′,3,3′-benzophenonetetracarboxylic dianhydride, 3,3′-oxydiphthalic dianhydride, 2,3,6,7-naphthalene tetracarboxylic acid dianhydride, or the combination thereof.

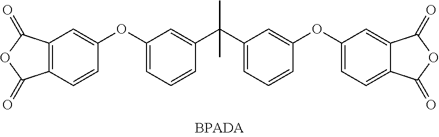 [SMILES: CC(C)(c1cccc(Oc2ccc3c(c2)C(=O)OC3=O)c1)c1cccc(Oc2ccc3c(c2)C(=O)OC3=O)c1]

Exemplary diamines include but not limited to 4,4′-oxydianiline (ODA), 4,4′-diaminodiphenylmethane (MDA), 4,4′-diaminodiphenyl ether (DADE), 4,4′-diaminodiphenyl sulfide (ASD), 4,4′-diamino diphenyl sulfone (DDS), 2,2-bis(3-amino-4-hydroxylphenyl)hexafluoropropane (6FAP), 3,3′-diamino-4,4′-dihydroxy diphenyl ether, 3,4′-diamino-3′,4-dihydroxy diphenyl ether, 4,4′-diamino-3,3′-dihydroxy diphenyl ether, 3,3′-diamino-4,4′-dihydroxy diphenyl methane, 3,4′-diamino-3′,4-dihydroxy diphenyl methane, or 4,4′-diamino-3,3′-dihydroxy diphenyl methane.

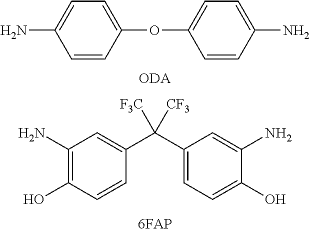

After the aforementioned diamine was dissolved in a polar aprotic solvent, for example, N,N-dimethylformamide (DMF), N,N′-dimethylacetamide (DMAc) or N-methylpyrrolidone (NMP), the aromatic dianhydride represented by Formula 2 was added to formed polyimide precursor (polyamic acid (PPA)). The reactive functional group, such as —OH or —COOH, was introduced after imidizing the above mentioned polyamic acid to obtain the aromatic polyimide having at least two reactive terminal groups (PI—OH).

The following is an example for forming the aromatic polyimide having at least two reactive terminal groups (PI—OH).

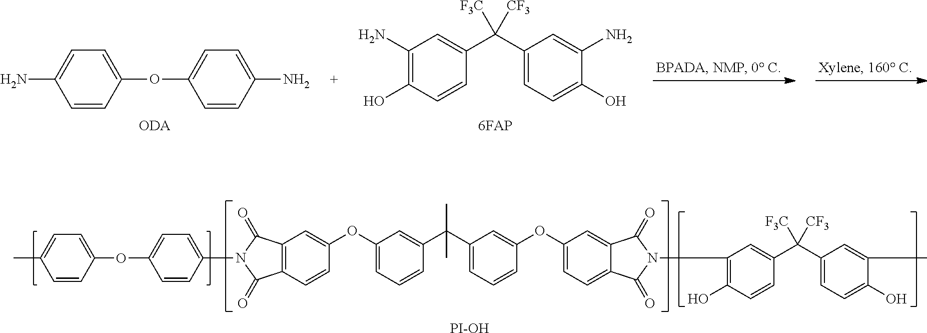

2.00 g (0.02 mol) of ODA and 3.66 g (0.01 mol) of 6FAP were dissolved in 20 g of NMP in a reaction flask under an N₂ atmosphere to form a solution, and put the reaction flask in an ice bath. 10.41 g (0.01 mol) of BPADA was dissolved in 20 g of NMP, and then slowly dropwise added to the above mentioned solution. After 5 hrs reaction, the ice bath was removed, the resultant was kept at room temperature and stirred for about 18 hour, followed by adding 40 mL of xylene and using a Dean stark apparatus to dehydrate at a temperature controlled of 160° C. for 8 hrs. Afterwards, 100 mL of MeOH was added to separate out PI—OH solid (Yield: 81%).

Photosensitive polyimide may be formed by reacting the aromatic polyimide having at least two reactive terminal groups with a compound having a photosensitive group, wherein the compound having the photosensitive group may be a compound having an acryloyl group at a terminal thereof, for example, methacryloyl chloride (MAC), acryloyl chloride (AC), or 2-chloroethyl methacrylate (CIEMA).

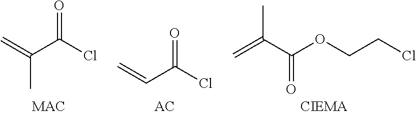

The formed photosensitive polyimide includes two side chains grafted to the aromatic polyimide backbone. For example, when the photosensitive polyimide was formed by an aromatic polyimide with methacryloyl chloride having the photosensitive group, the two side chains included in the photosensitive polyimide are (meth)acryloyl groups. Wherein, the aromatic polyimide backbone may comprise a repeating unit A represented by one of Formula 1-1, Formula 1-2, and Formula 1-3, or the combination thereof:

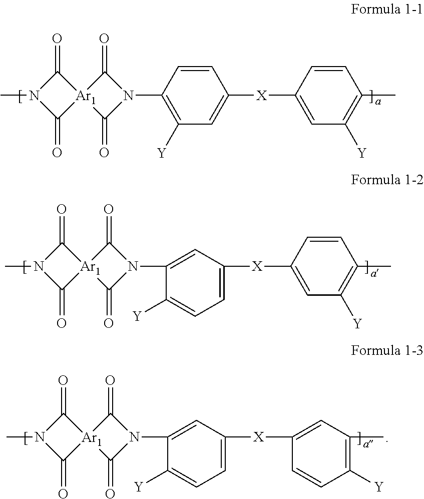

For example, the repeating unit A maybe above-mentioned Formula 1-3.

Wherein Ar₁ may be one of

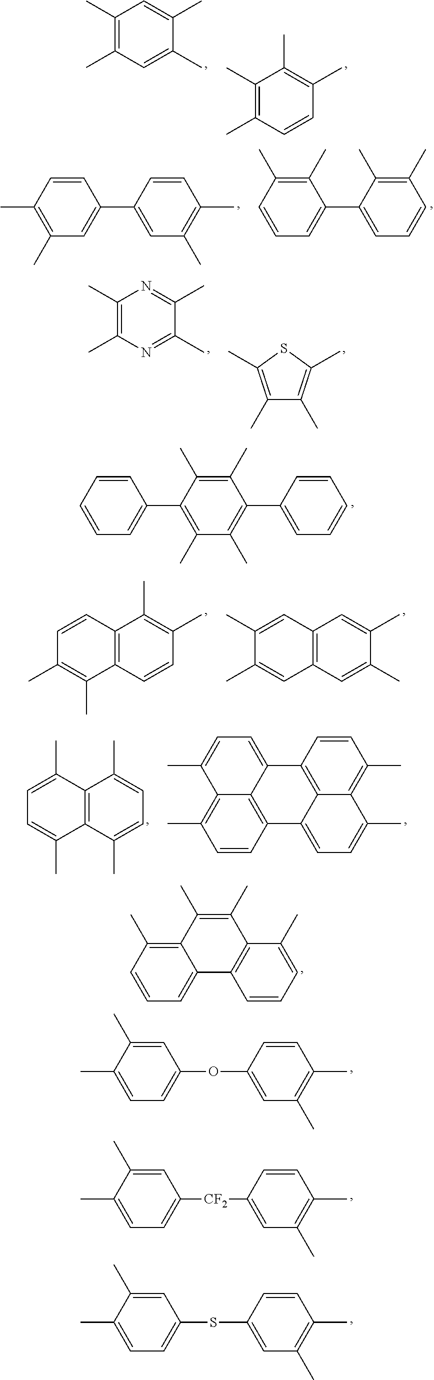

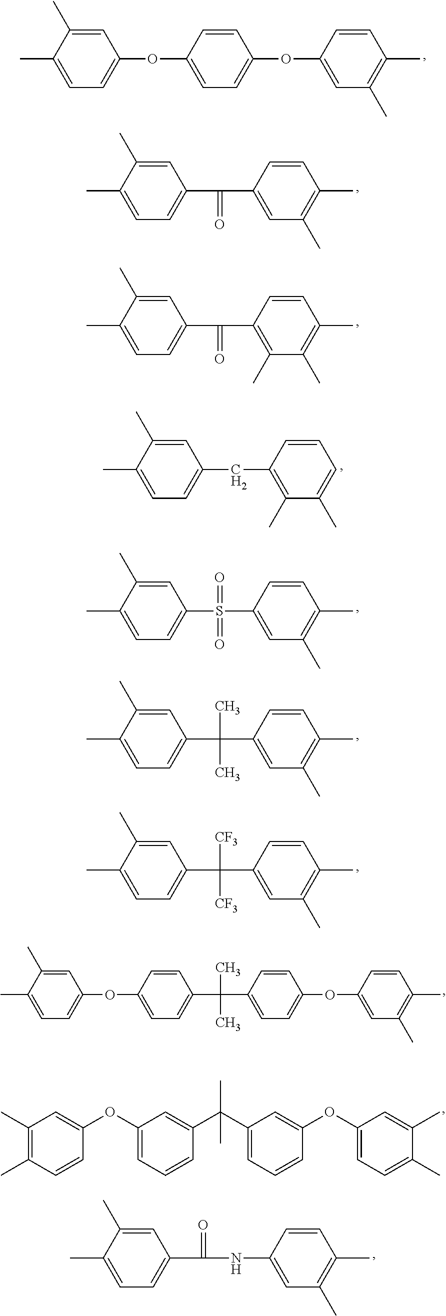

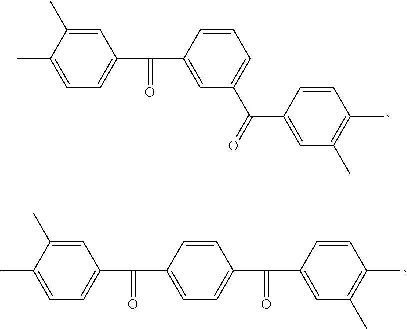

and a combination thereof. For example, Ar₁ may be

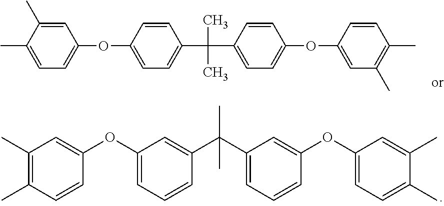

According to the diamine being used to formed the photosensitive polyimide, X may be one of

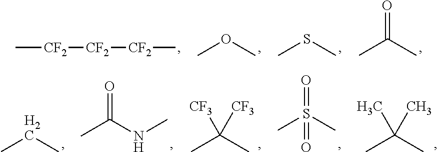

and a combination thereof. For example, X may be

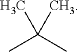

Y may be varied depending on the reactive functional group introduced. For example, when the reactive functional group introduced is —OH, Y is —O— bonded with the first side chain and the second side chain of the photosensitive group. a, a′, and a″ each are independently an integer of 1 or more, for example, a, a′, and a″ each are 1.

For example, the photosensitive polyimide may be represented by the following Formula 1-A:

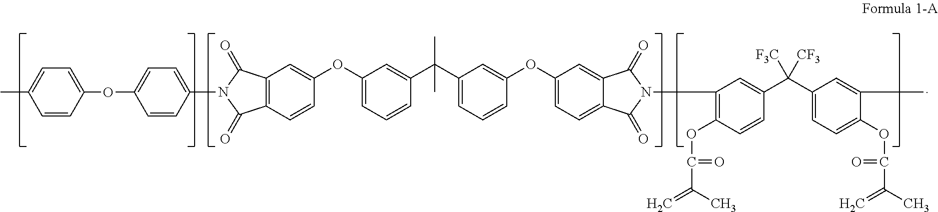

For example, the photosensitive polyimide may be represented by the following Formula 1-B:

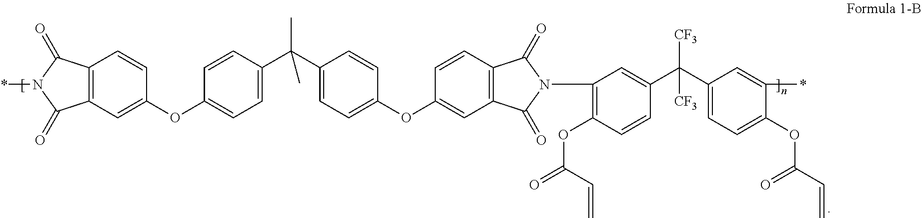

The following is the method of synthesizing the photosensitive polyimide represented by Formula 1-A.

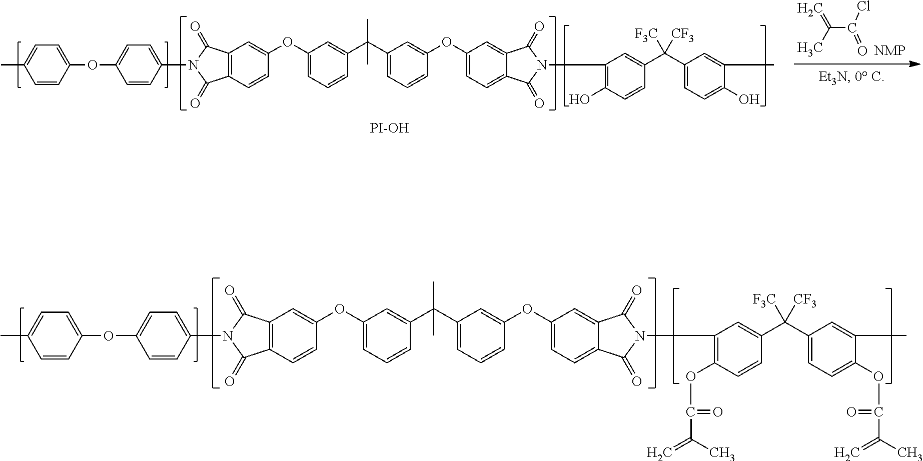

1 g of PI—OH was dissolved in 9 g of NMP (solid content: 10%). After the dissolution was completed, moved the solution into an ice bath, and 1 g of Et₃N (the weight ratio of Et₃N:PI—OH=1:1) was added. When the temperature down to 0° C., 1 g of methacryloyl chloride(MAC) was slowly added thereto (the weight ratio of MAC:PI—OH=1:1). After 8 hrs reaction, 100 mL of methanol was poured into the solution to separate out 0.82 g (Yield: 82%) of the compound represented by Formula 1-A.

A photoinitiator is any substance that generates free radicals when exposed to light. The free radicalS of the photoinitiator may further lead to polymerization reactions. By receiving energy from the ultraviolet (250-420 nm) or visible light (400-800 nm), the photoinitiator generates free radicals R., and the free radicals R. lead the curing/cross-linking polymerization of monomers. The photoinitiator receiving energy from the light of 200 nm-400 nm wavelength is preferred. The photoinitiator included in the photosensitive resin composition according to the present invention may be a photoinitiator 3022, a photoinitiator 309, a photoinitiator 302, a photoinitiator 207, a photoinitiator 184, a photoinitiator 173, or the combination thereof. The combination of the photoinitiator 3022 and the photoinitiator 309 is preferred.

A semiconductor package may be formed by coating a photosensitive resin composition on semiconductor chips or a base material. Wherein the base material may include, but is not limited to, a silicon wafer, a plastic substrate, or a ceramic circuit board.

A semiconductor package according to an embodiment of the present invention is formed by coating the photosensitive resin composition including the compound represented by Formula 1, the photoinitiator, and the photosensitive polyimide on the substrate undergoing exposure and development process, and post curing the photosensitive resin composition.

Hereinafter, the exemplary embodiments will be described in further detail with reference to an example and a comparative example. The following examples are merely in order to explain the exemplary embodiments, not to limit the exemplary embodiments.

### Example

The photosensitive resin composition in the example of the present invention includes the compound represented by Formula 1, which was formed by the process mentioned above, 3 (weight) % of the photoinitiator 3022 and 1 (weight) % of the photoinitiator 309, and the photosensitive polyimide represented by Formula 1-A, which was formed by the method mentioned above.

### Comparative Example

The photosensitive resin composition of the comparative example includes 3% of the photoinitiator 3022 and 1% of the photoinitiator 309, the photosensitive polyimide represented by Formula 1-A, which was formed by the method mentioned above, 1.5% of OFS-6030 silane, conventionally used as a crosslinker and 1.5% of diethylene glycol dimethacrylate, conventionally used as a coupling agent.

The experimental condition is shown below in Table 1.

TABLE 1

| | | | | | | | UV | | | |
|---|---|---|---|---|---|---|---|---|---|---|
| | spin coating | | | | coupling | | radiation | developing | | |
| Experiment | rate | PI | photoinitiator | crosslinker | agents | HQ | exposure | time | additive | result |
| Example | 1800/2200 | PR-PI | 3%: 3022 | — | — | 200 ppm | 1000 mJ | 90 seconds | 3% | resolution |
| | | | 1%: 309 | | | | | | CH10305 | 29 um |
| Comparative | 1800/2200 | PR-PI | 3%: 3022 | 1.5% | 1.5% | 200 ppm | 1000 mJ | 90 seconds | None | resolution |
| example | | | 1%: 309 | | | | | | | 43 um |

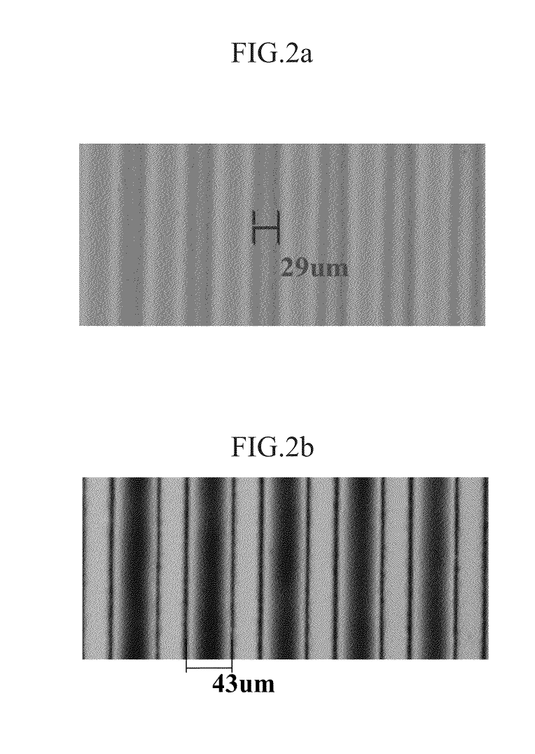

After the photosensitive resin composition according to the example and the comparative example were dissolved in NMP, respectively, the solution of the photosensitive resin composition according to the example and the solution of the photosensitive resin composition according to the comparative example were independently coated on different substrates with 1800/2200 rpm. The coatings were exposed to 1000 mJ UV radiation exposure, developed for 90 seconds, and post cured at 250° C. for 3 hr. The results of resolution were shown in FIGS. 2a and 2b.

From the above experiments, the compound represented by Formula 1 may replace OFS-6030 silane and diethylene glycol dimethacrylate, which were commercially available crosslinkers and coupling agents. In addition, the semiconductor package formed by the photosensitive resin composition of the example may result in better resolution.

While the invention has been particularly shown and described with reference to embodiments thereof, it will be understood by those of ordinary skill in the art that various changes in form and details may be made therein without departing from the spirit or scope of the present invention as defined by the following claims.

What is claimed is:

1. A compound represented by Formula 1, wherein n is an integer of 1 to 15:

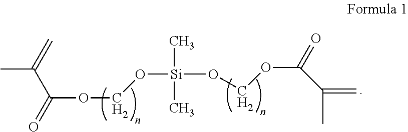

2. A photosensitive resin composition, comprising the compound according to claim 1, a photoinitiator, and a photosensitive polyimide.

3. The photosensitive resin composition according to claim 2, wherein the photosensitive polyimide comprise:
an aromatic polyimide backbone,
a first side chain, and
a second side chain,
wherein the first side chain and the second side chain each include a (meth)acryloyl group grafted to the aromatic polyimide backbone.

4. The photosensitive resin composition according to claim 3, wherein the aromatic polyimide backbone comprises a repeating unit A represented by one of Formula 1-1, Formula 1-2, Formula 1-3, and a combination thereof: 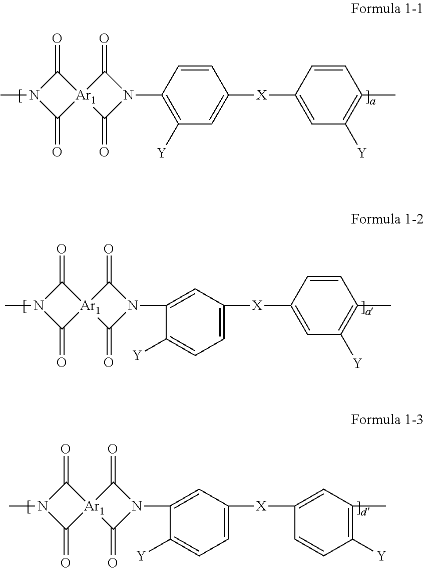
wherein Ar₁ is one of 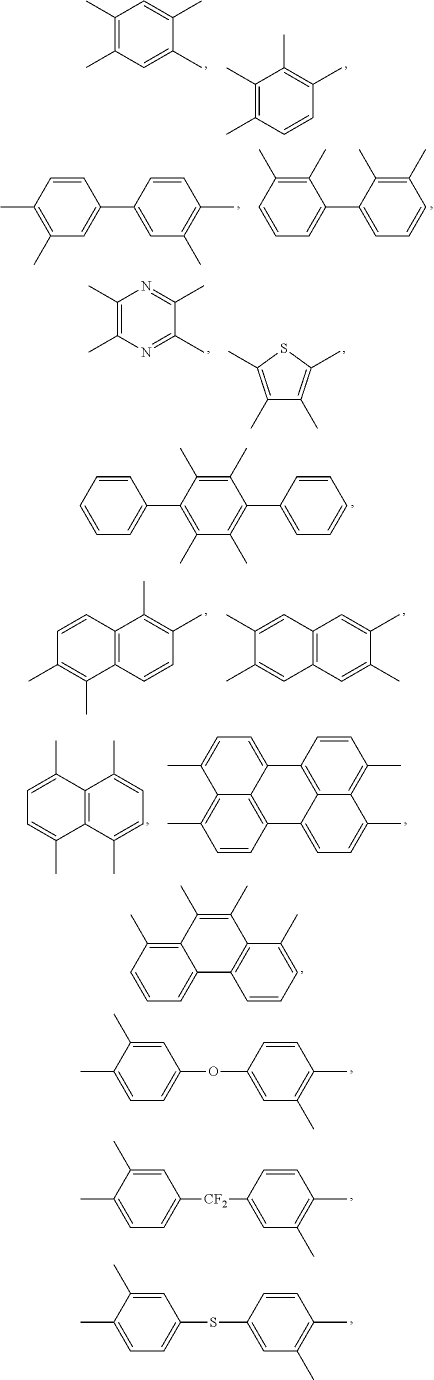 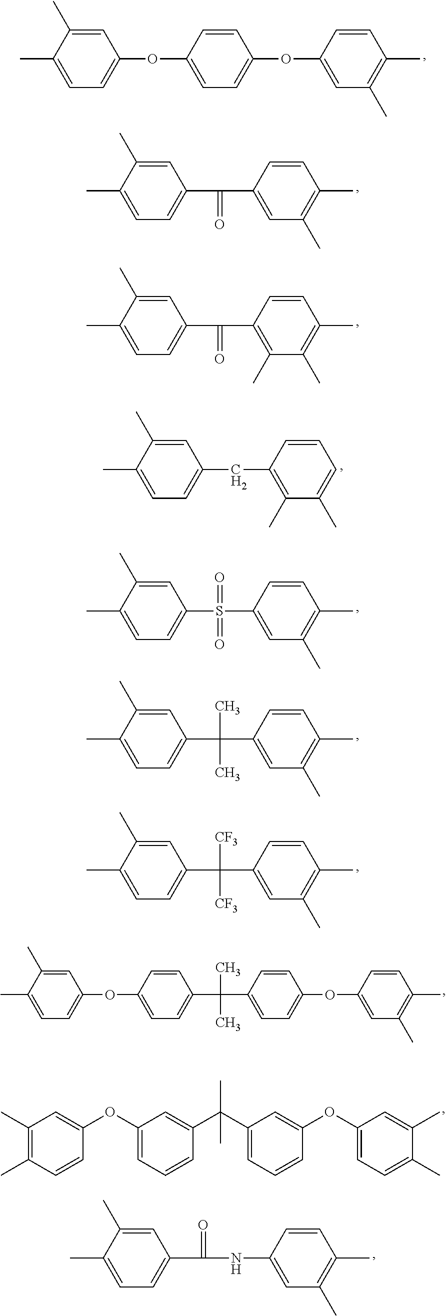 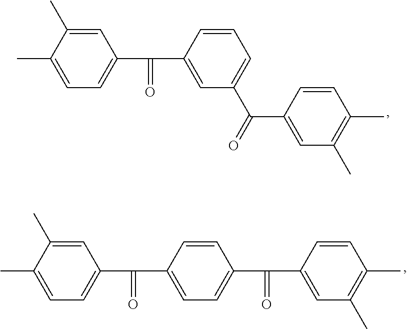
and a combination thereof;
X is one of 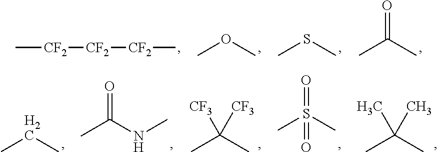
and a combination thereof;
Y is —O— which is bounded to the first side chain and the second side chain, and a, a′, and a″ each are independently an integer of 1 or more.

5. The photosensitive resin composition according to claim 4, wherein the photosensitive polyimide is represented by Formula 1-A:

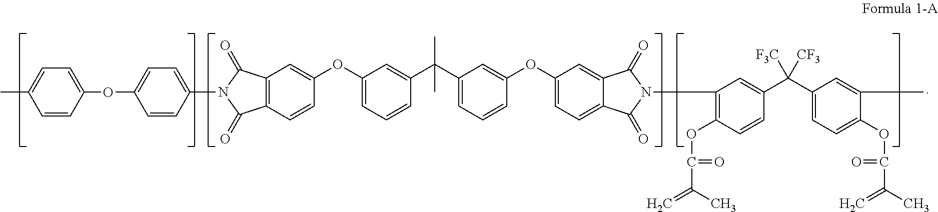

6. The photosensitive resin composition according to claim 4, wherein the photosensitive polyimide is represented by Formula 1-B:

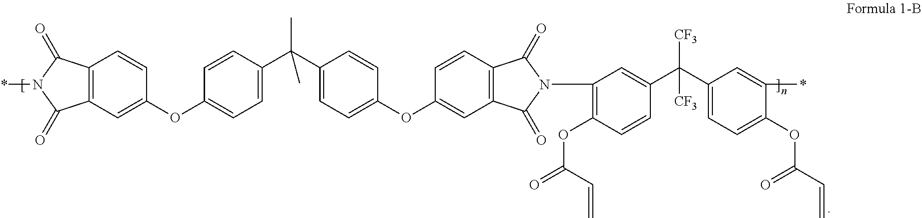

7. A semiconductor package, comprising:
a plurality of semiconductor chips; and
an insulation layer encapsulated the plurality of semiconductor chips, wherein the insulation layer is formed by curing the photosensitive resin composition according to claim 2.

8. The semiconductor package according to claim 7, wherein the photosensitive polyimide comprising:
an aromatic polyimide backbone,
a first side chain, and
a second side chain,
wherein the first side chain and the second side chain each include a (meth)acryloyl group grafted to the aromatic polyimide backbone.

9. The semiconductor package according to claim 8, wherein the aromatic polyimide backbone comprises a repeating unit A represented by one of Formula 1-1, Formula 1-2, Formula 1-3, and a combination thereof: 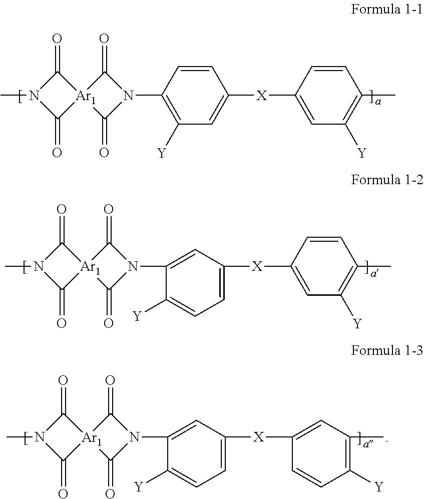
wherein Ar₁ is one of 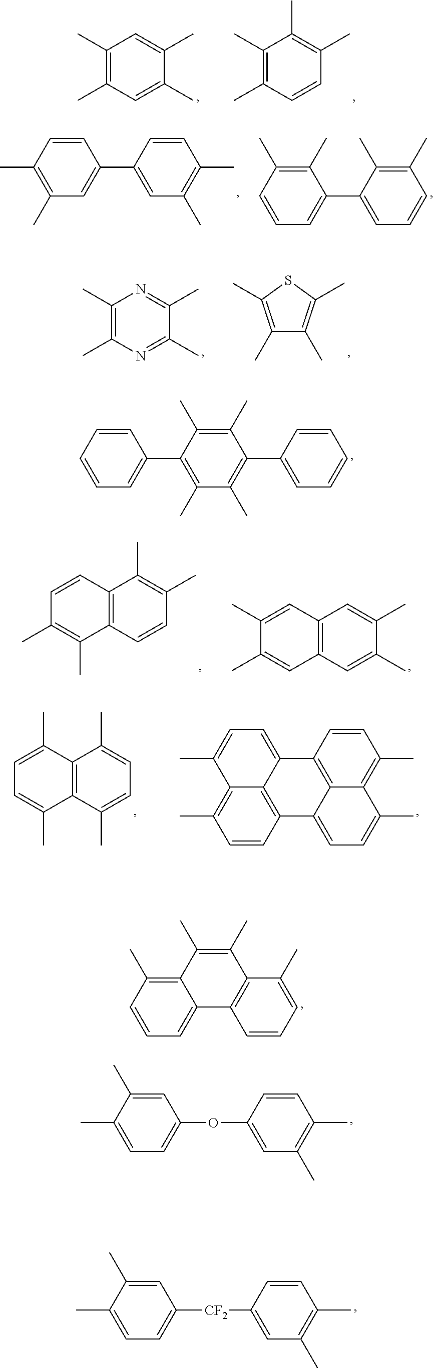 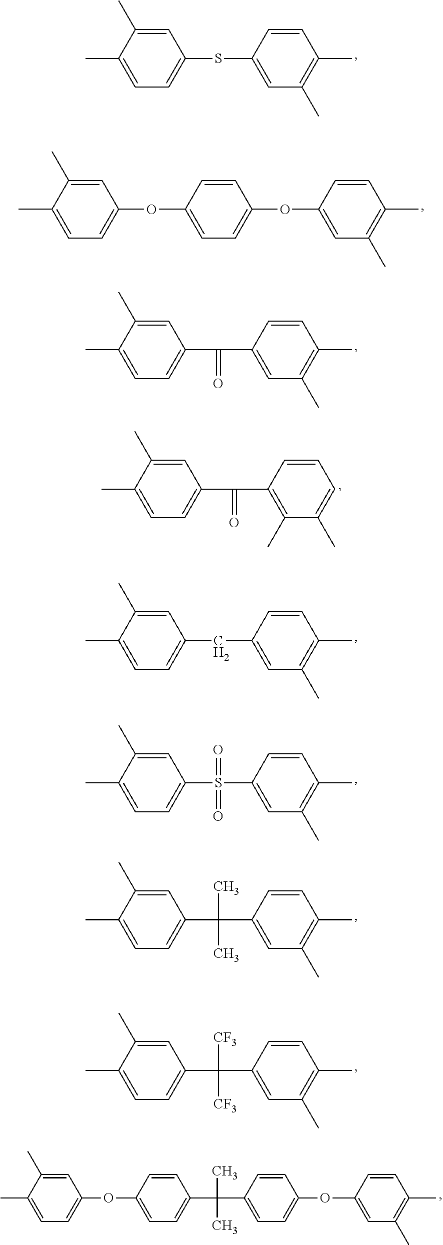 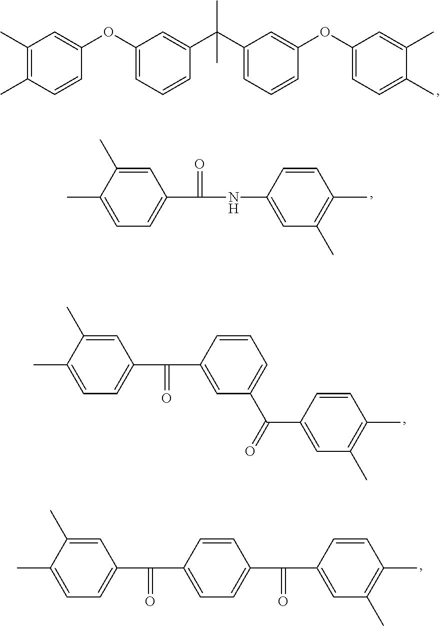
and a combination thereof;
X is one of 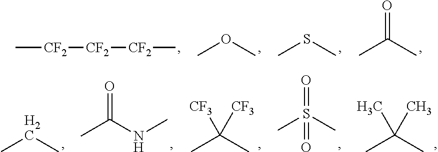
and a combination thereof;
Y is —O— which is bounded to the first side chain and the second side chain, and a, a′, and a″ each are independently an integer of 1 or more.

10. The semiconductor package according to claim 9, wherein the photosensitive polyimide is represented by Formula 1-A:

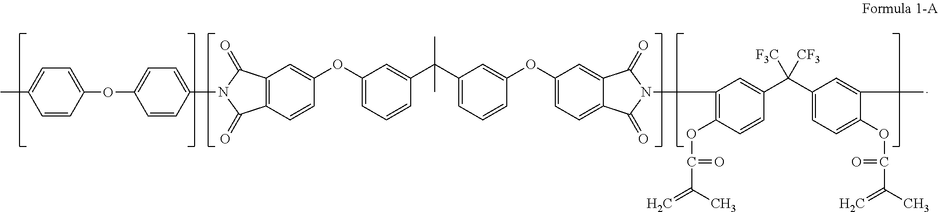

11. The semiconductor package according to claim 9, wherein the photosensitive polyimide is represented by Formula 1-B: [chemical structure]
